(19) United States
(12) Patent Application Publication
(10) Pub. No.: US 2010/0136712 A1
(43) Pub. Date: Jun. 3, 2010

(54) COMPOUND AND METHOD FOR PRODUCING THE SAME

(76) Inventors: HUI-YUN BOR, Longtan Township (TW); Chao-Nan Wei, Longtan Township (TW); Yuan-Pang Wu, Longtan Township (TW); Cuo-Yo Nieh, Longtan Township (TW); Jian-Hong Liao, Longtan Township (TW)

Correspondence Address: Dr. BANGER SHIA;Patent Office of Bang Shia, 102 Lindencrest Ct, Sugar Land, TX, 77479-5201, US

(21) Appl. No.: 12/326,284

(22) Filed: Dec. 2, 2008

(51) Int. Cl. H01L 21/02; C04B 35/48

(52) U.S. Cl. 438/3; 501/135; 257/E21.008

(57) ABSTRACT

The invention provides a Ti doped lead barium zirconate dielectric material which could be applied to high frequency devices. The material comprises a compound with the chemical formula (Pb_{I-X}Ba_{X})(Zr_{I-Y}Ti_{Y})O₃, wherein X is greater than 0.3 and smaller than 1; Y is greater than zero and smaller than 0.5. The said dielectric material is tunable. A method for producing a dielectric film comprises the following steps. Firstly, prepare a Ti doped lead barium zirconate dielectric material by a first process which is one chosen from a group consisting of a solid state process, a coprecipitation process, a sol-gel process, and a hydrothermal process. Secondly, integrate the dielectric material into a target device using a second process to form a dielectric film, wherein the second process is one chosen from a group consisting of a chemical solution deposition process, a sputtering process, a chemical vapor deposition process, and a pulse laser deposition process.

### BACKGROUND OF THE INVENTION

1. Field of the invention

The present invention relates generally to a dielectric material, and more particularly, the dielectric material is tunable and could be applied to high frequency microwave devices or other target devices such as semiconductor devices.

2. Description of the prior art

Capacitance structure made of dielectric materials has been applied to various kinds of devices such as arithmetic processor, memory element, high frequency communication devices, etc. Plenty of capacitance structures are required for those devices mentioned above. Take dynamic random access memory (DRAM) for example, with the trend of miniaturization, it is necessary to decrease the area of capacitance and increase the dielectric constant of materials more effectively. As for high frequency communication devices, the transmission of signals relies on the electromagnetic wave propagation, and the electromagnetic wave propagation is effected deeply by the characteristics of medium materials. Thus, much research is focusing on exploiting and probing into appropriate materials.

With the rapid development of ferroelectric ceramics in the 1990s, the dielectric constant ε of ferroelectric materials can be modulated by modulating the electric field according to research. The ferroelectric materials have a high dielectric constant, and the dielectric constant changes remarkably under a high electric field (E>100 kV/cm), changes in percentages of dozens.

To achieve better property, materials with both high tunability and low dielectric loss tangent are required. The temperature sensitivity of materials should also be a concern. Presently, ferroelectric materials popularly researched include SrTiO₃, BaTiO₃, BaSrTiO₃, and PbZrTiO₃, etc.

### SUMMARY OF THE INVENTION

Accordingly, an aspect of the present invention is to provide a dielectric material with good tunability, low dielectric loss tangent and low temperature sensitivity.

An embodiment of the invention provides a Ti doped lead barium zirconate dielectric material. The Ti doped lead barium zirconate dielectric material comprises a compound with the chemical formula (Pb_{I-X}Ba_{X})(Zr_{I-Y}Ti_{Y})O₃. According to a preferred embodiment, X is greater than 1 and smaller than 0.3; Y is greater than 0 and smaller than 0.5.

Another aspect of the present invention is to provide a method for producing a dielectric film, formed by Ti doped lead barium zirconate dielectric material comprising a compound with the chemical formula (Pb_{I-X}Ba_{X})(Zr_{I-Y}Ti_{Y})O₃. Wherein X is greater than 1 and smaller than 0.3; Y is greater than 0 and smaller than 0.5.

According to another embodiment of the invention, the method for producing a dielectric film is comprised of the following steps. Firstly, prepare a Ti doped lead barium zirconate dielectric material by a first process, wherein the first process could be, but not limited to, a solid state process, a coprecipitation process, a sol-gel process, and a hydrothermal process. Secondly, integrate the Ti doped lead barium zirconate dielectric material into a target device using a second process to form the dielectric film, wherein the second process could be, but not limited to, a chemical solution deposition process, a sputtering process, a chemical vapor deposition process, and a pulse laser deposition process.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 illustrates a side view of a Ti doped lead barium zirconate dielectric material disposed on a substrate according to an embodiment of the invention.

FIG. 2 is a flow chart demonstrating a process of producing the Ti doped lead barium zirconate dielectric material according to an embodiment.

FIG. 3 illustrates the samples in the embodiment with different relative density resulting from different Ti dopant and different sinter temperature.

FIG. 4 is a flow chart demonstrating a process of producing the Ti doped lead barium zirconate dielectric film according to an embodiment.

FIG. 5 illustrates the difference of the dielectric property with different Ti content for the films.

FIG. 6A illustrates the difference of the dielectric property with different sinter temperature for the lead barium zirconate film without Ti.

FIG. 6B illustrates the difference of the dielectric property with different sinter temperature for the lead barium zirconate films with different Ti content.

FIG. 7A illustrates the difference of the tunability for the films with different Ti content.

FIG. 7B is the figure of merit (FOM, tenability divided by dielectric loss tangent) of the films with the change of Ti content.

### DETAILED DESCRIPTION OF THE INVENTION

The present invention provides a Ti doped lead barium zirconate dielectric material with good tunability, low dielectric loss tangent and low sensitivity of temperature.

According to an embodiment of the invention, the Ti doped lead barium zirconate dielectric material could be applied to a high frequency device. The Ti doped lead barium zirconate dielectric material comprises a compound with the chemical formula (Pb_{I-X}Ba_{X})(Zr_{I-Y}Ti_{Y})O₃. According to a preferred embodiment, X is greater than 1 and smaller than 0.3; Y is greater than 0 and smaller than 0.5.

According to a preferred embodiment, when the Ti doped lead barium zirconate dielectric material is applied to a high frequency device, the thickness of the high frequency device is larger than 100 nm and smaller than 5 μm.

When the Ti doped lead barium zirconate dielectric material is applied to an integrated circuit, the Ti doped lead barium zirconate dielectric material is disposed on a substrate. The substrate could be, but not limited to, a semiconductor substrate such as Si substrate or GaAs substrate, or an oxide substrate such as MgO substrate, SrTiO₃ substrate or LaAlO₃ substrate.

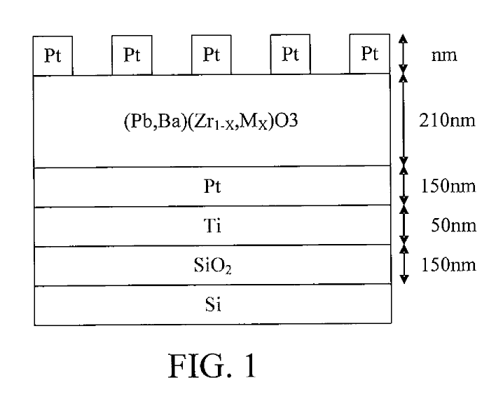

Please refer to FIG. 1. FIG. 1 illustrates a side view of a Ti doped lead barium zirconate dielectric material disposed on a substrate according to an embodiment of the invention. Wherein the thickness of the Ti doped lead barium zirconate dielectric material is 210 nm in the embodiment; the structure of the substrate is Pt/Ti/SiO₂/Si, and the substrate with this structure is prepared by the following steps.

Initially, the p type of Si substrate with (100) orientation is cleaned by a standard cleaning process. The next, SiO₂ is grown on the Si substrate as an insulating layer (the thickness is 150 nm in the embodiment) by a wet thermal oxidation process. Subsequently, Ti is deposited on the SiO₂ layer as a buffer layer (the thickness is 50 nm in the embodiment) by a dual E-gun evaporation process. Particularly, the buffer layer is in order to improve the adhesion between the SiO₂ layer and the Pt layer which is deposited on the Ti layer later on. The substrate with Pt/Ti/SiO₂/Si structure is eventually sintered at 400° C. for 30 minutes under a nitrogen atmosphere.

Another aspect of the present invention is to provide a method for producing a dielectric film, formed by Ti doped lead barium zirconate dielectric material comprising a compound with the chemical formula (Pb_{I-X}Ba_{X})(Zr_{I-Y}Ti_{Y})O₃. Wherein X is greater than 1 and smaller than 0.3; Y is greater than 0 and smaller than 0.5.

According to another embodiment of the invention, the method for producing a dielectric film comprising the following steps. Firstly, prepare a Ti doped lead barium zirconate dielectric material by a first process, wherein the first process could be, but not limited to, a solid state process, a coprecipitation process, a sol-gel process, and a hydrothermal process. Secondly, integrate the Ti doped lead barium zirconate dielectric material into a target device using a second process to form the dielectric film, wherein the second process could be, but not limited to, a chemical solution deposition process, a sputtering process, a chemical vapor deposition process, and a pulse laser deposition process.

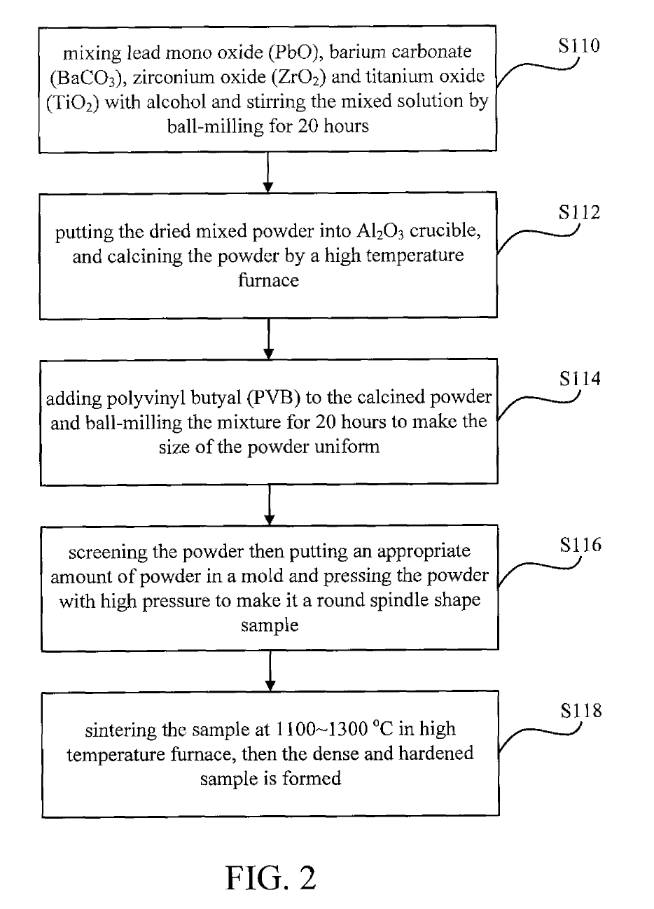

Please refer to FIG. 2. FIG. 2 is a flow chart demonstrating a process of producing the Ti doped lead barium zirconate dielectric material according to an embodiment. Wherein the process is a solid state process comprising the following steps.

Firstly, step S110 is performed to mix lead mono oxide (PbO), barium carbonate (BaCO₃), zirconium oxide (ZrO₂) and titanium oxide (TiO₂) with alcohol and stir the mixed solution by ball-milling for 20 hours. Secondly, step S112 is performed to put the dried mixed powder into Al₂O₃ crucible, and calcine the powder by a high temperature furnace. The next, step S114 is performed to add polyvinyl butyal (PVB) to the calcined powder and ball-mill the mixture for 20 hours to make the size of the powder uniform. After that, step S116 is performed to screen the powder then put an appropriate amount of powder in a mold and press the powder with high pressure to make it a round spindle shape sample. Finally, step S118 is performed to sinter the sample at 1100˜1300° C. in high temperature furnace then the dense and hardened sample is formed.

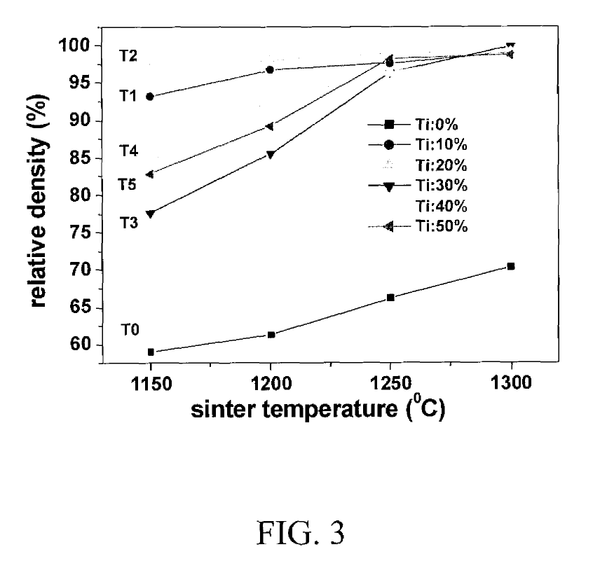

In the embodiment, the sample sintered at such temperature range has its phase diffraction peak. The information about the phase diffraction peak is from X-Ray diffraction analysis. Please refer to FIG. 3. FIG. 3 illustrates the samples in the embodiment with different relative density resulting from different Ti dopant and different sinter temperature. The relative density is measured by Archimedes method. Those samples without Ti dopant need higher sinter temperature to reach the relative density higher than 95%. Those samples doped with Ti can reach the same relative density with lower sinter temperature.

Table 1 shows the dielectric property of the samples with different content of Ti. Wherein sample A (PBZ) is lead barium zirconate dielectric material without Ti dopant; sample B (PBZT10) is lead barium zirconate dielectric material doped with 10% of Ti; sample C (PBZT20) is lead barium zirconate dielectric material doped with 20% of Ti; sample D (PBZT30) is lead barium zirconate dielectric material doped with 30% of Ti; sample E (PBZT40) is lead barium zirconate dielectric material doped with 40% of Ti; and sample F (PBZT50) is lead barium zirconate dielectric material doped with 50% of Ti. The relative density of the samples is higher than 95%, and sample A (without Ti) is sintered at 1450° C. while the others are sintered at 1300° C. Namely, those samples doped with Ti can have higher relative density with lower sinter temperature. Moreover, the dielectric constant ε of the samples increases significantly with the increase of Ti content, from 954.74 (sample A without Ti) to 2234.69 (sample F with 50% of Ti). Simultaneously, the dielectric loss tangent of the samples drops considerably then increases slightly with the increase of Ti content.

TABLE 1

| | | Relative | | |
|---|---|---|---|---|
| | Sinter temp. | density | Dielectric | Dielectric loss |
| Compound | (° C.) | (%) | constant ε | tanδ |
| Sample A | 1450 | 94.47 | 954.74 | 0.0096 |
| (PBZ) | | | | |
| Sample B | 1300 | 98.97 | 1432.11 | 0.0006 |
| (PBZT10) | | | | |
| Sample C | 1300 | 99.61 | 1506.19 | 0.0006 |
| (PBZT20) | | | | |
| Sample D | 1300 | 99.83 | 1602.28 | 0.0012 |
| (PBZT30) | | | | |
| Sample E | 1300 | 99.24 | 2008.25 | 0.0022 |
| (PBZT40) | | | | |
| Sample F | 1300 | 98.66 | 2234.69 | 0.0022 |
| (PBZT50) | | | | |

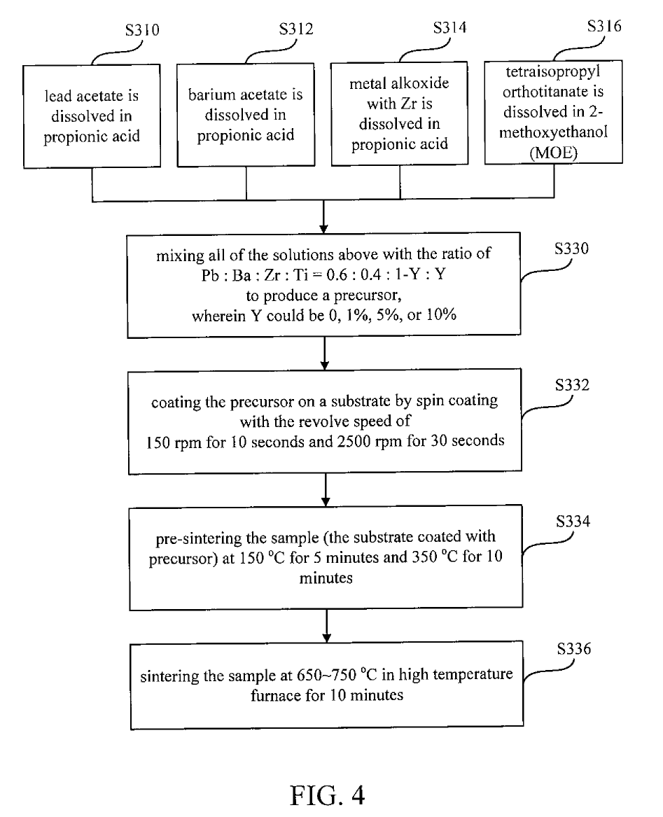

Please refer to FIG. 4. FIG. 4 is a flow chart demonstrating a process of producing the Ti doped lead barium zirconate dielectric film according to an embodiment. Wherein the process is a chemical solution deposition process comprising the following steps.

Initially, step S310 is performed to dissolve lead acetate in propionic acid and step S312 is performed to dissolve barium acetate in propionic acid. Simultaneously, step S314 is performed to dissolve metal alkoxide with Zr in propionic acid. Meanwhile, step S316 is performed to dissolve tetraisopropyl orthotitanate in 2-methoxyethanol (MOE). After that, step S330 is performed to mix all of the solutions above with the ratio of Pb:Ba:Zr:Ti=0.6:0.4:1-Y:Y to produce a precursor, wherein Y could be 0, 1%, 5%, or 10%. Subsequently, step S332 is performed to coat the precursor on a substrate by spin coating with the revolve speed of 150 rpm for 10 seconds and 2500 rpm for 30 seconds. Then, step S334 is performed to pre-sinter the film (the substrate coated with precursor) at 150° C. for 5 minutes and 350° C. for 10 minutes. Finally, step S336 is performed to sinter the film at 650˜750° C. in a high temperature furnace for 10 minute.

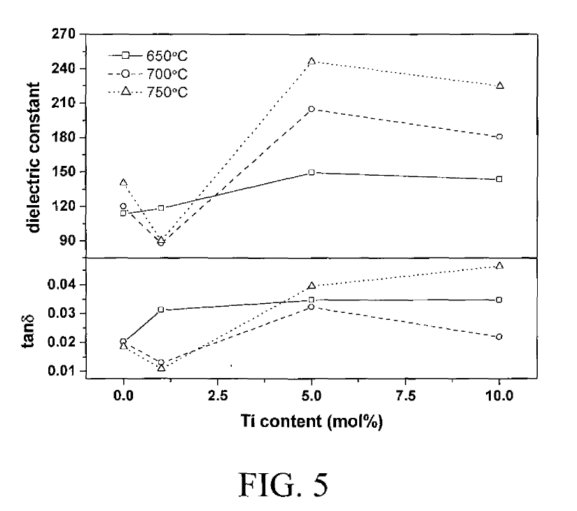

For the lead barium zirconate dielectric films doped with Ti, phase-transition temperature can be lowered 50° C. at such sinter temperature range. Besides, the films tend to crystallize with increasing the sinter temperature, wherein the crystal grains tend to distribute randomly without the appearance of orientation. The information about the phase diffraction is from X-Ray diffraction analysis. Please refer to FIG. 5. FIG. 5 illustrates the difference of the dielectric property with different Ti content for the films. The dielectric constant is measured under room temperature, zero bias, and the alternating frequency is 1 MHz. The dielectric constant of the films drops slightly and then increases considerably (maximum: 250) with the increase of Ti content. Meanwhile, the dielectric loss tangent of the films tends to increase with the increase of Ti content.

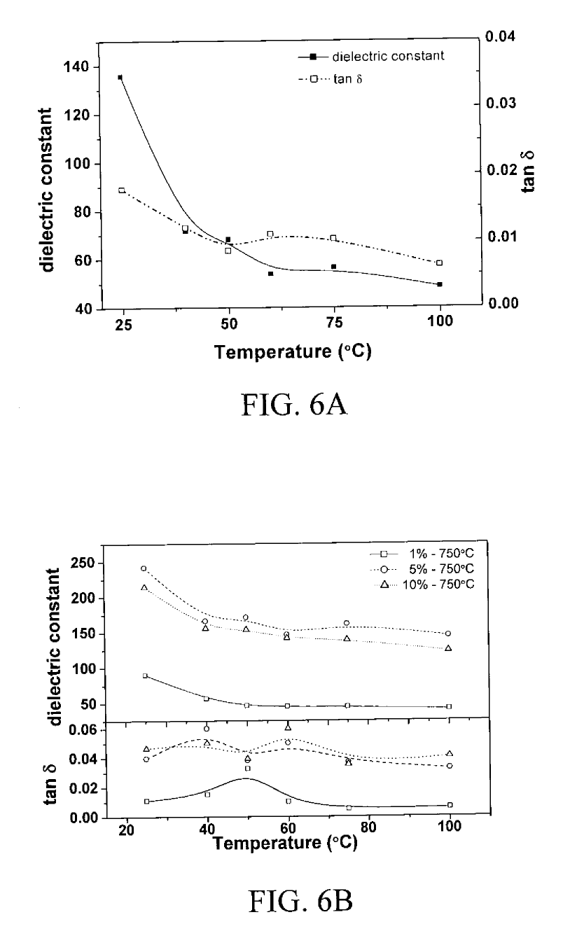

Please refer to FIG. 6A and FIG. 6B. FIG. 6A illustrates the difference of the dielectric property with different sinter temperature for the lead barium zirconate film without Ti. FIG. 6B illustrates the difference of the dielectric property with different sinter temperature for the lead barium zirconate films with different Ti content. For the lead barium zirconate film without Ti, the dielectric constant decreases from 140 at room temperature to 50 at 100° C., changes in percentages of 60%. With the increase of Ti content, the dielectric constant of the film decrease more slightly with the increase of the temperature, changes in percentages of 30%. Namely, the films doped with Ti have lower sensitivity of temperature.

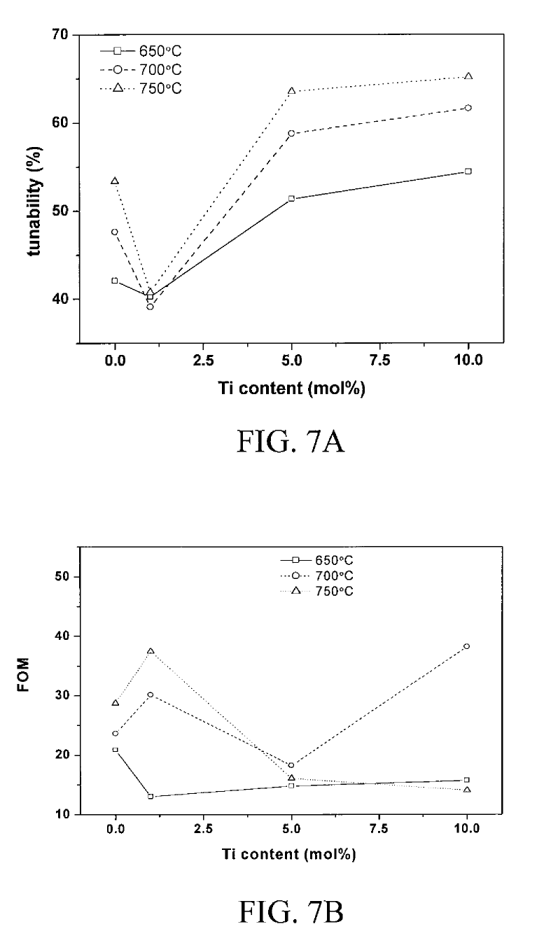

Please refer to FIG. 7A. FIG. 7A illustrates the difference of the tunability for the films with different Ti content. Under the bias of 500 kV/cm, the maximum tenability is 65%. FIG. 7B is the figure of merit (FOM, tenability divided by dielectric loss tangent) of the films with the change of Ti content. The maximum figure of merit (FOM) is 40.

To summarize, it is easy to see that the lead barium zirconate dielectric material has higher dielectric constant, higher tunability, and lower sensitivity of temperature with Ti dopant.

Although the present invention has been illustrated and described with reference to the preferred embodiment thereof, it should be understood that it is in no way limited to the details of such embodiment, and is capable of numerous modifications within the scope of the appended claims.

What is claimed is:

1. A Ti doped lead barium zirconate dielectric material comprising a compound with the chemical formula (Pb_{I-X}Ba_{X})(Zr_{I-Y}Ti_{Y})O₃; wherein X is greater than 0.3 and smaller than 1; Y is greater than zero and smaller than 0.5.

2. The Ti doped lead barium zirconate dielectric material of claim 1, wherein when the Ti doped lead barium zirconate dielectric material is applied to a high frequency device, the thickness of the high frequency device is greater than 100 nm and smaller than 5 μm.

3. The Ti doped lead barium zirconate dielectric material of claim 1, wherein when the Ti doped lead barium zirconate dielectric material is applied to an integrated circuit, the Ti doped lead barium zirconate dielectric material is disposed on a substrate.

4. The Ti doped lead barium zirconate dielectric material of claim 3, wherein the substrate is a semiconductor substrate or an oxide substrate.

5. The Ti doped lead barium zirconate dielectric material of claim 4, wherein the semiconductor substrate is a Si substrate or a GaAs substrate.

6. The Ti doped lead barium zirconate dielectric material of claim 4, wherein the oxide substrate is an MgO substrate, a SrTiO₃ substrate or a LaAlO₃ substrate.

7. A method for producing a dielectric film, the method comprising the following steps:
preparing a Ti doped lead barium zirconate dielectric material by a first process, wherein the Ti doped lead barium zirconate dielectric material comprises a compound, and the chemical formula of the compound is:
(Pb_{I-X}Ba_{X})(Zr_{I-Y}Ti_{Y})O₃; wherein X is greater than 0.3 and smaller than 1; Y is greater than zero and smaller than 0.5; and
integrating the Ti doped lead barium zirconate dielectric material into a target device using a second process so as to form the dielectric film.

8. The method of claim 7, wherein the first process is one chosen from a group consisting of a solid state process, a coprecipitation process, a sol-gel process, and a hydrothermal process.

9. The method of claim 7, wherein the second process is one chosen from a group consisting of a chemical solution deposition process, a sputtering process, a chemical vapor deposition process, and a pulse laser deposition process.

10. The method of claim 7, wherein the target device is a semiconductor device or a high frequency device.
